(19) United States
(12) Patent Application Publication
(10) Pub. No.: US 2007/0085616 A1
(43) Pub. Date: Apr. 19, 2007

(54) A method for steering an oscillator and an oscillator

(76) Inventor: Sampo Aallos, Tampere (FI)

Correspondence Address: STITES & HARBISON PLLC, 1199 NORTH FAIRFAX STREET, SUITE 900, ALEXANDRIA, VA, 22314, US

(21) Appl. No.: 10/570,342

(22) PCT Filed: Sep. 5, 2003
(86) PCT No.: PCT/FI03/00655

§ 371 Date: Nov. 8, 2006

(51) Int. Cl. H03B 5/32

(52) U.S. Cl. 331/158

(57) ABSTRACT

A method to control a frequency oscillator, as a crystal oscillator, and to form an oscillating circuit in order to produce a frequency oscillator improved to its qualities, in which the frequency of reference oscillator (1) is changed by means of frequency multiplier (2) into output frequency. As frequency oscillator a low frequency oscillator (1) is used, the control of which output frequency (5) is carried out adjusting the low frequency oscillator (1) by means of control arrangement (4).

The invention relates to a method for steering a frequency oscillator, as a crystal oscillator, and to form an oscillating circuit, by means of which method a frequency oscillator improved to its qualities is achieved.

Previously known from U.S. Pat. No. 6,160,458 is a crystal oscillator circuit able to function on an extensive temperature range. The oscillating circle includes a temperature detector with digital output, control circuit, memory and compensation circuit, on the basis of which the frequency of temperature is effected.

In U.S. Pat. No. 6,175,284 a temperature compensated crystal oscillator circuit is also known, which has a standard voltage circuit maintaining the crystal oscillator. The arrangement includes a temperature detector, circuit of frequency difference, direct-current load, from which there is feedback coupling to the circuit of frequency difference and maintenance of the direct-current load, whereat by means of control from the circuit of frequency difference the variations of the crystal oscillator circuit are temperature compensated.

In the above presented crystal oscillators the frequency of oscillation is close to the output frequency, which is usually within the range of 10 MHz-32 MHz. With the above solutions the frequencies of crystal oscillators working close to these frequencies have fine control. The manufacture of the crystal oscillator is the harder the greater the range where it functions. Also the size of the oscillator gets bigger and its sensitivity to disturbances from the outside grows.

With the frequency oscillator according to the invention and the method to control it, a remarkable improvement of the reliability, resistance against blows and great G-powers of typical crystal oscillators is achieved. The invention is characterized in what is presented in the claims.

The aim of the invention is to produce a frequency oscillator, i.e. more precisely a crystal oscillator that would function reliably in spite of external disturbances and would have easy control in order to retain a frequency meant for it. The aim is reached choosing as frequency oscillator an oscillator crystal with much lower range than the output frequency or a corresponding mechanical resonator, the frequency of which is typically under 100 kHz. Such an oscillator is small sized and easy to manufacture and it also has the capacity to retain very well the frequency meant for it in spite of external disturbances. The power consumption of the oscillator is small thanks to the small size, which is important in Blue Tooth applications, for instance. With the frequency multiplier the low range oscillation is changed to necessary high range oscillation, i.e. to over 10 MHz frequency. Low range oscillation can be changed to high range oscillation also by growing the frequency by means of a phase locked loop in a manner known per se. With such an oscillator an extensive frequency range is achieved, since changing the multiplier of the frequency multiplier or using the phase locked loop as output plenty of wanted frequencies are achieved and from an extensive frequency range.

A low frequency oscillator is adjusted by voltage based or digital based control and, if necessary, also the impact of changes in temperature is by control of the compensation signal compensated to control the oscillator. To put it more accurately, the method as per the invention is characterized in that as frequency oscillator a low frequency oscillator with substantially lower frequency than wanted is used, the output frequency of which is multiplied using the frequency multiplier or the frequency is raised by means of a phase locked loop in order to achieve higher frequency and the control of the output frequency is carried out adjusting the low frequency oscillator by means of the control arrangement.

The frequency oscillator according to the invention is characterized in that it comprises a low frequency (<100 Hz) oscillator and its control circuit has a voltage control or digital control arrangement for control of the output frequency adjusting the said frequency oscillator of low frequency.

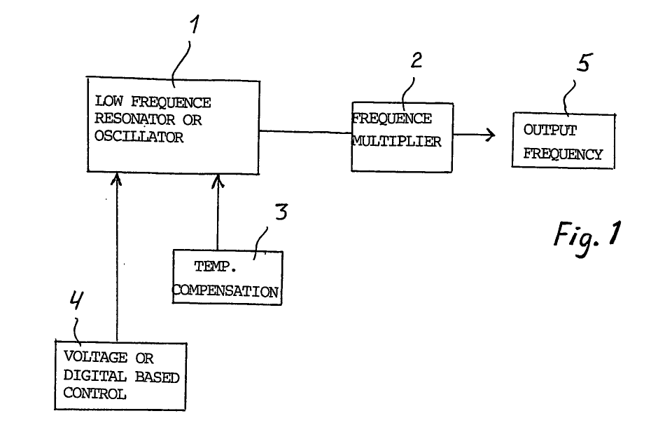

In the following the invention is disclosed with reference to the enclosed drawing FIG. 1, which shows schematically the frequency oscillator according to the invention.

FIG. 1 shows as frequency oscillator 1 a resonator of a structure known as such or a reference oscillator crystal, the frequency of which is considerably lower than the wanted output frequency 5. The example frequency for oscillator 1 is under 100 kHz, for instance most suitably 32 kHz. Such a frequency oscillator is small sized, only about 1×2 mm, it is thin and drop resistant and tolerates remarkable accelerations, at least 5000 G from different directions. However, in spite of these advantageous qualities the frequency oscillator 1 must be adjusted against disturbance factors. According to the invention low frequency oscillator 1 is adjusted so that that its frequency remains stable. For adjustment either control based on voltage censored from the oscillator or digital based control is used.

Aiming at a temperature compensating frequency converter and for instance at a frequency converter covering a range of −40°-+130° C., the oscillator must be furnished with compensation 3 of thermal effect. The control from this compensation circuit is fed to control the low frequency oscillator 1.

Since reference oscillator 1 is a low frequency unit, to the frequency oscillator on the whole a frequency multiplier component 2 must be connected, by means of which the adjusted frequency of oscillator 1 is converted into wanted high frequency of output 5, as a frequency over 10 MHz. For instance, the frequency generally used is 24 MHz. With frequency multiplier 2 the frequency is raised at least to a hundredfold. If the frequency is increased using the phase locked loop correspondingly the frequency is also raised to a hundredfold.

In case of disturbance the impact of disturbance on the frequency can immediately be eliminated from frequency oscillator 1 by control and adjustment of frequency oscillator 1. In the solution according to known publication on page 1 adjusting control is taken to the frequency multiplier, whereat the reference oscillator may remain disturbed for a longer time. In order to turn the situation into normal it then requires that all the time the frequency of the basic oscillator must be detected and controlled and also the frequency multiplier controlled. This makes the solution complicated.

A low frequency oscillator is easier to manufacture and smaller sized, so that by means of it a high frequency oscillator produced according to the invention is still small sized and reliable in use.

1. A method to control a frequency oscillator, as a crystal oscillator, and to form an oscillating circuit, by means of which method a frequency oscillator, improved to its qualities, is achieved, in which method the frequency of reference oscillator (1) is raised by means of frequency multiplier (2) or phase locked loop into output frequency (5), characterized in that as frequency oscillator a low frequency oscillator (1) with substantially lower frequency (<) 100 kHz) than wanted is used, the control of which output frequency (5) is carried out adjusting the low frequency oscillator (1) by means of voltage or digital control arrangement (4).

2. A method according to claim 1 characterized in that the impact on frequency due to changes of temperature is eliminated feeding temperature compensation control (3) to the low frequency oscillator (1).

3. A method according to claim 1 characterized in that the low frequency is raised at least to a hundredfold.

4. A frequency oscillator, as a crystal oscillator, the high frequency output frequency (5) (<10 MHz) is achieved by means of frequency multiplier (2) connected to oscillator (1) or by means of a phase locked loop, characterized in that the frequency oscillator includes low frequency (<)100 kHz) oscillator (1) and its control circuit includes voltage or digital control arrangement (4) for control of output frequency in adjusting the said low frequency oscillator (1).

5. A frequency oscillator according to claim 4 characterized in that control (3) compensating the impact of the change of temperature is connected to the low frequency oscillator (1).
